(19) United States
(12) Patent Application Publication
(10) Pub. No.: US 2009/0160475 A1
(43) Pub. Date: Jun. 25, 2009

(54) Test pin reduction using package center ball grid array

(76) Inventors: Anwar Ali, San Jose, CA (US); Thinh Tran, San Jose, CA (US); Wilson Choi, San Jose, CA (US)

Correspondence Address: LSI Corporation c/o Suiter Swantz pc llo, 14301 FNB Parkway, Suite 220, Omaha, NE, 68154, US

(21) Appl. No.: 12/004,131

(22) Filed: Dec. 20, 2007

(51) Int. Cl. G01R 31/26; G06F 17/50

(52) U.S. Cl. 324/765; 716/4

(57) ABSTRACT

An apparatus and method for reducing the number of package pins in a chip package which must be budgeted for test purposes. In one embodiment, the invention achieves this by housing test balls in the depopulated center of a package ball array. The test balls are used to test a chip package prior to connection with a printed wiring board (PWB)/printed circuit board (PCB). After tests are completed, and when the chip package is connected to a PWB/PCB, the test balls may be left electrically isolated and unconnected. In another embodiment, the test balls are located in previously unused interstitial sites in a package ball array.

### CROSS-REFERENCE TO RELATED APPLICATIONS

[none]

### BACKGROUND OF THE INVENTION

1. Field of Invention

The present invention relates generally to the field of chip packaging, in particular ball grid array packaging.

2. Description of Related Art

Traditional approaches in chip packaging involve using dedicated package pins to control testability, including driving circuits in to a quiescent state. This results in a reduction of package pins available for functional I/Os, which poses a particular problem for designs with low I/O count which target small package body sizes (the physical footprint of a package attached to a printed wiring board). For applications targeting small body sizes, it is typical for the center of the package ball array to be depopulated simply to enable printed wiring board escape.

IC test, both at wafer and package level, requires dedicated test pins which can be controlled from package balls. These test pins are used to control signals chip testability, including reset of the test logic, and placing circuits in to a quiescent state. The exact number of test signals required varies according to the specific test methodology used. The presence of these test pins must be budgeted into the total pin count of the package. For example, if a design has 50 functional I/Os, and also requires eight dedicated test signals, the package must therefore support a total of 58 signals. For small body size packages, these signals must be placed on the periphery of the package to enable board escape. This is because balls closer to the package edge are easier to escape on the board than those further inside.

FIG. 1 shows a prior technique of ball grid array packaging. Because one can only escape a limited number of ball rows deep from the package edge due to printed wiring board (PWB)/printed circuit board (PCB) limitations, there is both a limit to the number of ball rows in the package, as well as an empty space, unutilized, at the center of the package, shown in FIG. 1 as 100.

Existing solutions use a combination of approaches to minimize the proportion of package balls which must be allocated for test purposes. One of the more commonly adopted methods to reduce test signal count, that is, to reduce the number of dedicated test signals that are required. This is accomplished through multiplexing test signals with standard functional I/Os, eliminating unnecessary test pins, or a combination of both. Various IC tests are also eliminated as part of this process. However, the disadvantage of this approach is that sharing test pins with standard I/Os increases test logic complexity. The result is an increase is cells required in the design, thereby increasing die area. It also increases tester time which reduces throughput of devices than can be tested in a production environment. This increases the total cost of the part.

Another existing solution is for eliminating test pins altogether, which reduces test coverage, making the part more susceptible to quality issues and failures. This results in an increase in defects and scraped units in customer systems. Hence, one can decrease the functional signal count in a chip. In order to fit the total package balls in to a given package body size, the number of functional I/O can be reduced after budgeting for test signals. Thus in an example where the total number of available package balls is 84 (see FIG. 1), this configuration would theoretically enable a total of 84 I/Os including power and ground supplies. However, due to printed wiring board (PWB) limitations, no balls can be placed further than three rows deep since the customer has determined they cannot connect them on the PWB. This ball row limitation is driven by the limitations in PWB layers and density, and is application specific. If for example six balls, marked as the solid balls 10 in FIG. 1, are needed to be dedicated for test purposes, the result is that only 78 (84−6) balls are now available for standard I/Os. Hence the total number of I/Os used in the IC needs to be reduced to 78. Furthermore, reducing signal I/O count of a design reduces its functionality.

A further existing solution is to increase package body size. However, for a fixed number of balls rows deep from the edge, increasing the package size increases the perimeter length, thereby increasing the number of package balls. Further disadvantages of this approach include increasing the package body size results in an increase in package cost; more circuit board space must be budgeted, and this may not be possible in applications where space is restricted.

Yet another existing solution is to decrease package ball pitch. The package ball is the ball on the package which is attached to the circuit board, and is also known as the package pin. The pitch (center to center spacing) of package balls can be reduced, which allows more package balls to be inserted for the same package body size, thereby enabling signal I/Os to be added. However, disadvantages of this approach include that reducing the package ball pitch makes it harder to escape on the printed circuit board since the ball spacing is tighter. In most cases this option would have already been examined as part of determining how many ball rows deep are acceptable.

Further, an existing solution is to increase the PWB layers or density. The number of PWB layers can be increased, or the use of tighter geometry design rules can be adopted such that balls deeper in to the package can be added for signals. However, disadvantages of this approach include increasing the cost of the PWB.

What is lacking in the prior art is a method and apparatus for utilizing empty space in a ball grid array for testing and debugging a IC microchip, such as taught in the present invention.

### SUMMARY OF THE INVENTION

Accordingly, an aspect of the present invention is to utilize the center of the package ball array, the empty ball array region, which is depopulated simply to enable printed wiring board escape, in order to insert test balls (which include other debug balls), which are not used during normal chip operation. More functional I/O balls are therefore available than in prior art packages.

A further aspect of the present invention is a method of increasing the number of available I/O signals available on the package, whilst also maintaining package pins for test purposes.

The sum total of all of the above advantages, as well as the numerous other advantages disclosed and inherent from the invention described herein, creates an improvement over prior techniques.

The above described and many other features and attendant advantages of the present invention will become apparent from a consideration of the following detailed description when considered in conjunction with the accompanying drawings.

### BRIEF DESCRIPTION OF THE DRAWINGS

Detailed description of preferred embodiments of the invention will be made with reference to the accompanying drawings. Disclosed herein is a detailed description of the best presently known mode of carrying out the invention. This description is not to be taken in a limiting sense, but is made merely for the purpose of illustrating the general principles of the invention. The section titles and overall organization of the present detailed description are for the purpose of convenience only and are not intended to limit the present invention.

FIG. 1 is plan view of a prior technique of ball grid array packaging.

FIG. 2A is a plan view of a first embodiment of the chip package contact region in accordance with the present invention.

FIG. 2B is a side view of the first embodiment of the chip package assembly showing the chip package contact region contacting a test board.

FIG. 2C is a side view of the first embodiment of the chip package assembly showing the chip package contact region contacting a customer PWB.

FIG. 3 is a plan view of an alternative embodiment of the chip package contract region of the present invention.

FIG. 4 is a flowchart for a method of practicing the present invention.

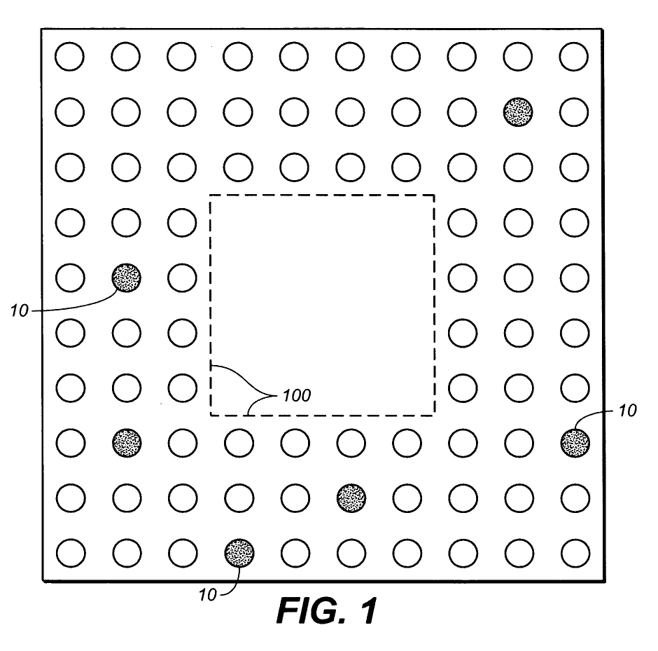

It should be understood that one skilled in the art may, using the teachings of the present invention, vary embodiments shown in the drawings without departing from the spirit of the invention herein. In the figures, elements with like numbered reference numbers in different figures indicate the presence of previously defined identical elements.

### DETAILED DESCRIPTION OF THE INVENTION

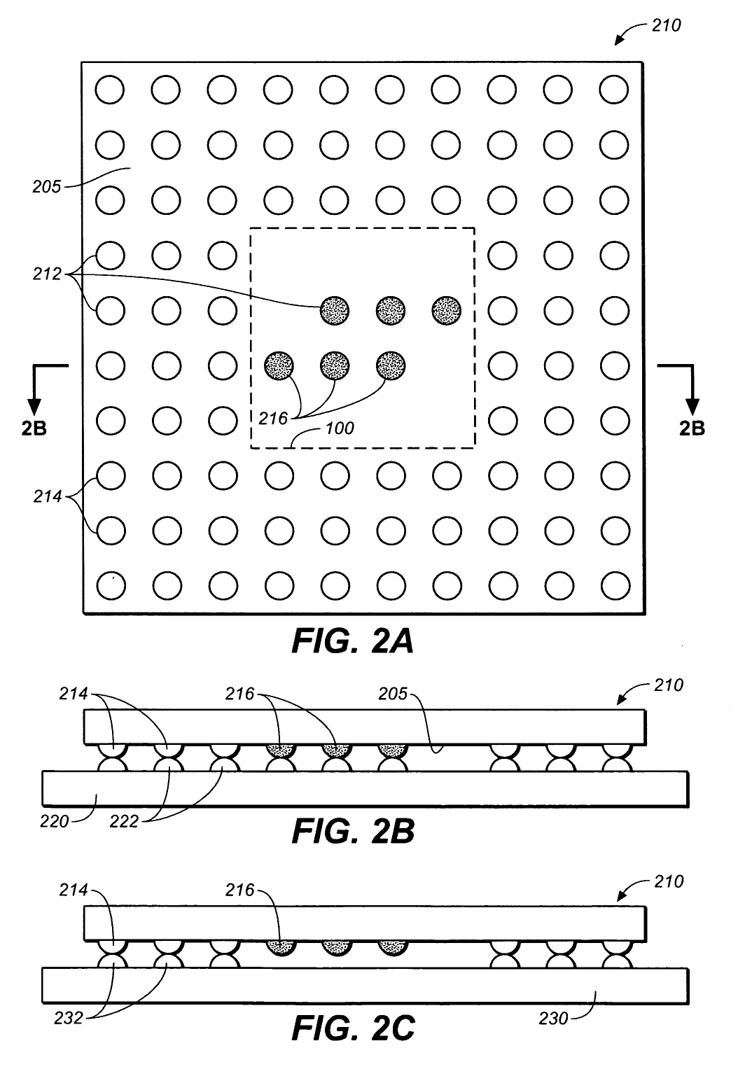

In a preferred embodiment, the apparatus of the present invention comprises the package assembly shown in FIG. 2. FIG. 2A is a plan view of a first embodiment of the chip package contact region of a modified ball grid array IC package in accordance with the present invention. A planar surface 205 in a semiconductor chip package assembly 210 has a plurality of equal rectilinearly spaced package balls 212 as shown, of which a first plurality of balls 214, indicated by the absence of shading, are package balls for functional I/O, power, or ground supplies. These balls 214 can be designated non-test balls or pins, or outer-array balls or pins, to distinguish them from a second plurality of balls, test balls 216, which can be also termed inner array balls or test signal balls or pins, shown in FIG. 2A by solid cross-sectional shading. These inner array balls 216 are found in the region at the center of a package assembly planar surface that is depopulated simply to enable printed wiring board escape. Of course in practice, depending on the configuration, either of balls 214 or 216 can carry any kind of signal, even test signals, if the balls are electrically connected to a PCB, and the non-test balls 214 are not precluded from also carrying test signals, which are ordinarily carried by the test balls 216 prior to the attachment of test balls 216 of the package assembly to a PWB/PCB. Further, the term “ball” is used throughout because typically the electrical connection formed on a package is in fact round in cross-section for manufacturing reasons, but it should be understood that this is a term of convenience and in fact a ball can simply be any shaped electrically conducting connector, unless otherwise noted.

The non-test balls are the primary I/O conduit to a die inside the chip package assembly 210 after the chip package has been tested in a fab or assembly plant. The chip package 210 houses a die or chip (not shown), which may be electrically attached to the balls 212 through wire bond or flip chip techniques, or any other design.

Due to the requirements and limitations of Printed Wiring Board (PWB) and PWB escape in present chips, the entire planar surface 205 of the chip package assembly 210 cannot be populated with non-test balls 214 when the chip package is attached to a PWB. Consequently, there is a region depopulated by non-test balls, termed the depopulated region of the chip package. The present invention teaches placing the test balls 216 in this depopulated region, separate from the non-test balls, shown as the dotted line square region 100 in FIG. 2A, with the test balls being the package balls used to test the package assembly (and chip or chips therein) while the package assembly is still being tested in a fab and prior to attachment to a customer PWB/PCB (hereinafter simply PCB). Since test signals are only for manufacturing use and not needed during normal chip operation, test specific balls are placed in the center of the package ball array area. This center area is unusable by the customer PCB in any case due to PCB escape issues, and is therefore always free. In FIG. 2A the balls outside the depopulated region 100 comprise the outer ball array of non-test balls 214.

As shown in FIG. 2B, dedicated test hardware 220, such as an ATE (Automated Test Equipment) or other specialized IC testing hardware, may be used to connect to test balls 216 in the depopulated region 100, which are electrically connected to test logic in the chip assembly 210, when the chip package assembly 210 is still being tested, prior to attachment to a PCB. Dedicated test hardware 220 has balls 222 that make contact with both non-test balls 214 and test balls 216. Redesigning the dedicated test hardware 220 is expensive but redesigning such hardware to access the depopulated region 100 and test balls 216 therein is economically feasible, as it allows for more test pins to be available to test a die in a chip package, and is long-term cheaper than redesigning the chip package as in prior techniques, and also avoids some of the disadvantages associated with prior techniques in adding more test pins.

As shown in FIG. 2C, once testing is completed and the chip package 210 is shipped to a customer for attachment to a PCB 230, the test balls or pins 216 are either left floating and/or grouped together and tied to a common ground or power, to disable the test logic associated with the test balls, and to electrically isolate the test balls 216. If the test signal pins are left floating, the I/O buffers on the die in the chip package 210 can use internal pull-ups or pull-downs so that the chip does not inadvertently drift into a test mode. As shown in FIG. 2C, when the chip package 210 contacts the PCB 230, the embodiment of FIG. 2A would contact a customer PCB 230 in the same manner as a traditional chip package not made in accordance with the present invention, with the non-test balls 214 contacting corresponding balls 232 on the PCB 230, but the test balls 216 would hang suspended as shown, mechanically and electrically isolated.

Several advantages follow from employing the present invention as shown herein. First, package I/O count is increased; the package ball count available for functional I/Os, powers, and grounds are all increased. Consequently, more I/O function can be incorporated in to the design. In addition, package body size is reduced. Conversely, for the same I/O count, the package body size required can be reduced, thereby reducing cost.

By employing the present design, additional test pins can be added to improve test coverage. Additional test balls can be added without penalty to regular I/O counts. Adding test balls can allow more extensive testing or debug to be done which improves quality and therefore end-product cost.

Further, employing the present invention simplifies tester hardware design. Since test balls are placed in a more predictable location (the package ball array center), test hardware can be better optimized to reduce cost and simplify test board design variations.

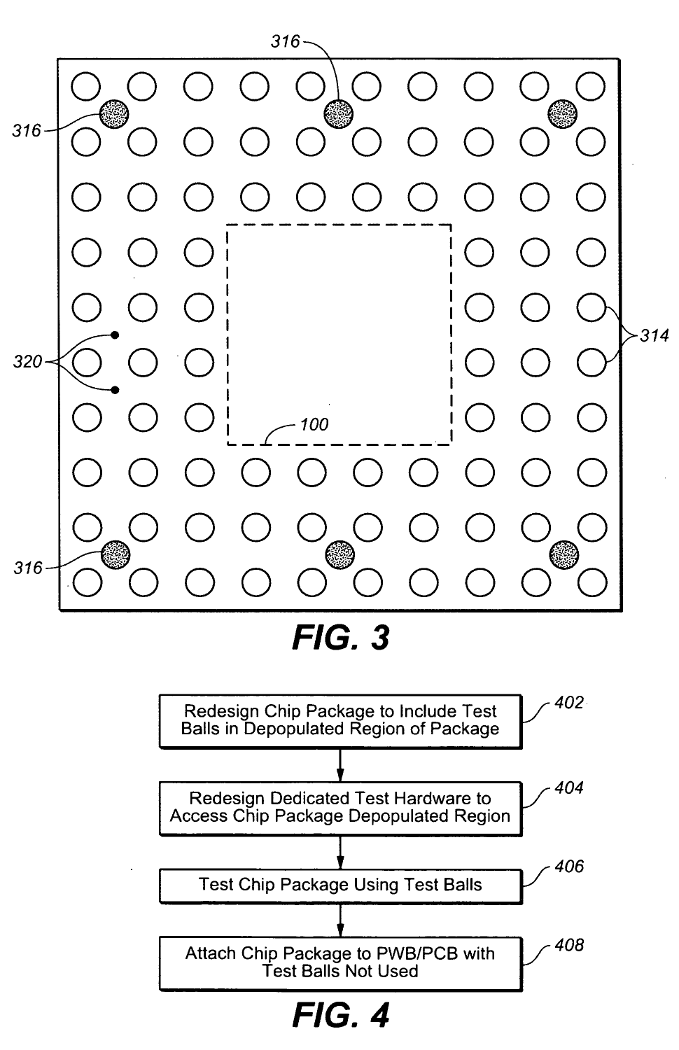

In addition to the embodiment of FIG. 2A, alternative configurations may be employed for the semiconductor chip package assembly of the present invention, as shown in FIG. 3. By way of illustration and not limitation, and referring to the descriptions herein, the non-test balls 314 and test balls 316 may be arrayed as shown, with the test specific balls 316, indicated by solid shading in FIG. 3, located in interstices 320 amongst regular function I/O package balls, such as outer ball array non-test balls 314, with the interstices formed by the spaces between the rows and columns of regularly spaced non-test balls. As before, the test hardware will be redesigned to use a PCB technology to access these test balls 316, similar to FIG. 2B. Instead of on-chip methods to pull-up or pull-down floating test balls during normal IC operation, one I/O package ball can be used to enable/disable these test I/Os. This package ball can then by tied on the customer PCB.

The approach of FIG. 3 can also be used to insert other debug signals not used during customer operation. The approach can also be used to provide alternate functionality when the package is mounted on to a different PCB which is designed to connect these additional package balls. Thus in the FIG. 3 embodiment the test balls 316 can either be left floating, not contacting anything, similar to the FIG. 2A embodiment as shown in FIG. 2B, or the test balls of the FIG. 3 embodiment can connect with additional package balls on a customer PCB.

The method of practicing the present invention comprises designing a package assembly in accordance with the principals of having extra test pins or test balls that are located in a heretofore unused part of a package assembly, as shown by the representative embodiments of FIGS. 2 and 3. The test equipment associated with traditional package assemblies not designed according to the present invention would be redesigned to allow electrical and mechanical contact between the test equipment and a package assembly designed in accordance with the present invention. The chip package assembly would be tested, using test balls as taught herein located in heretofore inaccessible regions, such as the depopulated empty ball array region of the FIG. 2A embodiment or the interstitial region of the FIG. 3 embodiment. After the test is completed, the test balls and/or the test logic associated with the test balls would be inactivated and electrically isolated, as taught herein, and the chip package assembly, such as assembly 210 in FIG. 2A, would be shipped to a customer for electrical connection to a PCB, such as PCB 230 in FIG. 2C. The combination of semiconductor chip package assembly and PWB or PCB (which, more generally, collectively and individually include any electronic component that connects to the chip package assembly), can be termed the IC package assembly.

Thus, turning attention to FIG. 4, and referring to the invention as disclosed herein, there is shown a simplified flowchart for the method of practicing the present invention. In step 402, labeled “Redesign Chip Package to Include Test Balls in Depopulated Region of Package”, a chip package is redesigned during the ASIC/IC design process to include test balls in the depopulated region of the package. In step 404, labeled “Redesign Dedicated Test Hardware to Access Chip Package Depopulated Region”, the dedicated test hardware, such as an ATE, is redesigned to enable access to the redesigned chip package depopulated region. In step 406, labeled “Test Chip Package Using Test Balls”, the test chip package is tested by the dedicated test hardware through the test balls. In step 408, labeled “Attach Chip Package to PWB/PCB with Test Balls Not Used”, the chip package, once tested, is attached to a PCB, and the test balls may or may not be used and/or electrically isolated from the PCB, depending on the embodiment of chip package; in the FIG. 2A embodiment, the test balls are not used when the chip package is attached to the PCB, while in the FIG. 3 embodiment, the test balls may or may not be used when attached to the PCB.

Although the present invention has been described in terms of the preferred embodiments above, numerous modifications and/or additions to the above-described preferred embodiments would be readily apparent to one skilled in the art.

It is intended that the scope of the present invention extends to all such modifications and/or additions and that the scope of the present invention is limited solely by the claims set forth below.

We claim:

1. A semiconductor chip package assembly comprising:
a chip package having a planar surface;
a first plurality of electrically conducting balls on said planar surface for conducting signals;
a second plurality of electrically conducting balls on said planar surface for conducting signals, said second plurality of electrically conducting balls conduct test signals; and,
wherein said second plurality of electrically conducting balls are on a separate region of said planar surface from said first plurality of balls.

2. The invention of claim 1, wherein:
said separate region comprises a depopulated region on said chip package planar surface.

3. The invention of claim 2, wherein:
said depopulated region comprises the center of said chip package planar surface.

4. The invention of claim 3, wherein:
said second plurality of balls conduct only test signals and are electrically isolated when not conducting test signals.

5. The invention of claim 4, wherein:
said balls comprise round cross-sectional electrical conductors, and said first and second pluralities of balls are equally spaced from their nearest neighbors in a substantially rectilinear manner.

6. The invention of claim 3, further comprising:
dedicated test hardware operatively connected to said chip package and having a plurality of balls that mate with said first and second plurality of balls of said chip package when said chip package is being tested; and,
wherein said second plurality of balls conduct only test signals when mated with said dedicated test hardware and are electrically isolated and do not conduct test signals when not mated with said dedicated test hardware.

7. The invention of claim 6, wherein:
said balls comprise substantially round cross-sectional electrical conductors, and
said first and second pluralities of balls are substantially equally spaced from their nearest neighbors.

8. The invention of claim 3, further comprising:
a PCB for connection to said chip package, operatively connected to said chip package; and,
said second plurality of balls conduct only test signals and are electrically isolated when on said IC package assembly.

9. The invention of claim 8, wherein:
said balls comprise substantially round cross-sectional electrical conductors, and
said first and second pluralities of balls are substantially equally spaced from their nearest neighbors.

10. The invention of claim 1, wherein:
said first balls are substantially equally spaced from their nearest neighbors, forming rows; and,
said second plurality of electrically conducting balls on said separate region of said planar surface from said first plurality of balls are located in the interstices of the rows of said first balls.

11. The invention of claim 10, wherein:
said second plurality of balls conduct only test signals and are electrically isolated when not conducting test signals.

12. The invention of claim 11, further comprising:
a PCB for connection to said chip package, operatively connected to said chip package, said PCB and chip package forming an IC package assembly;
wherein said second plurality of balls conduct only test signals and are electrically isolated when part of said IC package assembly.

13. The invention of claim 11, further comprising:
dedicated test hardware operatively connected to said chip package and having a plurality of balls that mate with said first and second plurality of balls of said chip package when said chip package is being tested; and,
wherein said second plurality of balls that conduct only test signals, conduct only test signals when mated with said dedicated test hardware and are electrically isolated and do not conduct test signals when not mated with said dedicated test hardware.

14. A method for designing and testing a package center ball grid array comprising the steps of:
designing a chip package having a planar surface;
designing on the chip package planar surface a first plurality of electrically conducting balls for conducting signals;
designing on the chip package planar surface a second plurality of electrically conducting balls for conducting signals, the second plurality of electrically conducting balls conducting test signals; and,
wherein the second plurality of electrically conducting balls are kept on a separate region of said planar surface from said first plurality of balls.

15. The method according to claim 14 comprising the steps of:
designing the chip package having the planar surface with an outer ball array of balls for conducting signals to and from the package assembly and a PCB;
designing the chip package to have a depopulated region in the center of the planar surface and outer ball array;
designing the chip package to have a plurality of inner array test balls located in the depopulated region at the center of the planar surface of the chip package, the test balls designed to operatively connect to dedicated test hardware to test the package assembly;
wherein the test balls conduct test signals when the package assembly is connected to the dedicated test hardware, and the test balls are electrically isolated when the package assembly is connected to the PCB.

16. The method of claim 15, further comprising the steps of:
designing dedicated test hardware to operatively connected to said package assembly, the dedicated test hardware having a plurality of balls that mate with said first and second plurality of balls of said chip package when said chip package is being tested; and,
wherein said second plurality of balls that conduct test signals, conduct only test signals when mated with said dedicated test hardware and are electrically isolated when not mated with said dedicated test hardware and are not conducting test signals.

17. The method of claim 15, further comprising the steps of:
designing a PCB for connection to said chip package, operatively connected to said chip package, said PCB and chip package forming an IC package assembly;
wherein said second plurality of balls that conduct test signals and are electrically isolated, do not conduct test signals when on said IC package assembly.

18. The method of claim 17, further comprising the steps of:
designing dedicated test hardware to operatively connected to said package assembly, the dedicated test hardware having a plurality of balls that mate with said first and second plurality of balls of said chip package when said chip package is being tested; and,
wherein said second plurality of balls that conduct test signals, conduct only test signals when mated with said dedicated test hardware and are electrically isolated when not mated with said dedicated test hardware.

19. An IC package assembly comprising:
a chip package having a planar surface;
a first plurality of electrically conducting balls on said planar surface for conducting signals;
a second plurality of electrically conducting balls on said planar surface for conducting signals;
a PCB electrically connected to said chip package and to said first plurality of balls; and,
wherein said second plurality of balls conducts signals only when the chip package is tested on dedicated test hardware, and does not electrically communicate with said PCB when connected to said PCB.

20. The invention of claim 19, wherein:
said first balls are substantially equally spaced from their nearest neighbors, forming rows;
said second plurality of balls are located in the interstices formed by the rows of said first plurality of electrically conducting balls; and,
said second plurality of balls mechanically contact said PCB when said chip package is connected to said PCB.
